(19) United States
(12) Patent Application Publication
(10) Pub. No.: US 2015/0110953 A1
(43) Pub. Date: Apr. 23, 2015

(54) TOUCH PANEL, METHOD FOR MANUFACTURING THE SAME, AND LIQUID CRYSTAL DISPLAY DEVICE INCLUDING THE TOUCH PANEL

(71) Applicant: LG INNOTEK CO., LTD., Seoul (KR)

(72) Inventors: Young Sun YOU, Seoul (KR); Yong Jin LEE, Seoul (KR); Kyoung Hoon CHAI, Seoul (KR); Dong Youl LEE, Seoul (KR); Young Jin NOH, Seoul (KR); Sun Young LEE, Seoul (KR)

(21) Appl. No.: 14/581,155

(22) Filed: Dec. 23, 2014

Related U.S. Application Data
(63) Continuation of application No. 13/979,570, filed on Jul. 12, 2013.

(30) Foreign Application Priority Data
Jan. 13, 2011 (KR) 10-2011-0003739

(51) Int. Cl. H01L 21/64

(52) U.S. Cl. CPC H01L 21/64; G06F 2203/04103
USPC 427/77

(57) ABSTRACT

A touch panel includes a substrate including at least one concave part, and a transparent electrode formed in the concave part to detect a position.

### CROSS-REFERENCE TO RELATED APPLICATIONS

This application is a continuation of U.S. application Ser. No. 13/979,570, filed Jul. 12, 2013, which is the U.S. national stage application of International Patent Application No. PCT/KR2012/000231, filed Jan. 10, 2012, which claims priority to Korean Patent Application No. 10-2011-0003739, filed Jan. 13, 2011, which are hereby incorporated by reference in their entirety.

### BACKGROUND

1. Technical Field

The disclosure relates to a touch panel, a method for manufacturing the same, and a liquid crystal display device including the touch panel.

2. Background of the Invention

Recently, a touch panel, which performs an input function through the touch of an image displayed on a display device by an input device such as a stylus pen or a hand, has been applied to various electronic appliances.

The touch panel may be mainly classified into a resistive touch panel and a capacitive touch panel. In the resistive touch panel, glass is shorted with an electrode due to the pressure of the input device so that a touch point is detected. In the capacitive touch panel, the variation in capacitance between electrodes is detected when a finger of the user is touched on the capacitive touch panel, so that the touch point is detected.

In this case, in order to pattern the electrode, various manufacturing processes such as a process of forming a mask and a process of depositing electrode materials are required. Accordingly, the manufacturing process may be complicated, and the manufacturing cost may be increased.

In general, the electrode includes ITO (indium tin oxide). When the electrode is manufactured by depositing the ITO, the thin deposition thickness is formed, so that high resistance is represented in the electrode.

Therefore, a touch panel including the electrode material substituting for the ITO, and an electrode formed by using the electrode material through a simple process is required, respectively.

### DISCLOSURE OF INVENTION

### Technical Problem

The embodiment relates to a touch panel and a method for manufacturing the same in which the manufacturing process can be simple, and the process cost can be reduced.

### Solution to Problem

According to the embodiment, there is provided a touch panel including a substrate including at least one concave part, and a transparent electrode formed in the concave part to detect a position.

### Advantageous Effects of Invention

As described above, in the touch panel according to the embodiment and the method for manufacturing the same, since the concave part is formed in the substrate, and the electrode is formed in the concave part, the manufacturing process is simplified. Accordingly, the manufacturing process and the manufacturing cost can be reduced. In particular, when the transparent electrode of the 2-layer touch panel is formed, since an additional film or an additional substrate can be omitted, the stack structure of the touch panel can be simplified. Accordingly, the transmittance can be improved, and the thickness can be reduced. When the electrode is formed in the concave part, the electrode may be formed by using an electrode material substituting for conventional ITO.

### BRIEF DESCRIPTION OF DRAWINGS

FIG. 1 is a sectional view showing a touch panel according to a first embodiment;

FIG. 2 is a sectional view showing a touch panel according to a second embodiment;

FIG. 3 is a sectional view showing a touch panel according to a third embodiment;

FIGS. 4 to 9 are sectional views showing a method for manufacturing the touch panel of FIG. 9; and

FIG. 10 is a sectional view schematically showing a liquid crystal display device.

### MODE FOR THE INVENTION

In the description of the embodiments, it will be understood that, when a layer (or film), a region, a pattern, or a structure is referred to as being “on” or “under” another substrate, another layer (or film), another region, another pad, or another pattern, it can be “directly” or “indirectly” over the other substrate, layer (or film), region, pad, or pattern, or one or more intervening layers may also be present. Such a position of the layer has been described with reference to the drawings.

The thickness and size of each layer shown in the drawings may be exaggerated, omitted or schematically drawn for the purpose of convenience or clarity. In addition, the size of elements does not utterly reflect an actual size.

Hereinafter, embodiments of the present invention will be described in detail with respect to accompanying drawings.

Hereinafter, a touch panel 100 according to the first embodiment will be described with reference to FIG. 1. FIG. 1 is a sectional view showing the touch panel according to the first embodiment.

Referring to FIG. 1, in the touch panel 100 according to the first embodiment, a transparent electrode 20 may be formed on a substrate 10 to detect an input device. In addition, interconnections 30 connected to the transparent electrode 20 and a printed circuit board 40 capable of connecting the interconnections 30 to an external circuit (not shown) may be provided.

If an input device such as a finger is touched on the touch panel, the difference in capacitance is made on a touched portion by the input device, and the touched portion representing the difference in the capacitance may be detected as a touch point.

Hereinafter, the touch panel 100 will be described in more detail.

After the transparent electrode 20 is formed on the substrate 10 having a concave part 10a, the interconnection 30 may be connected to the transparent electrode 20, and the printed circuit board 40 may be connected to the interconnection 30. In addition, a scattering prevention film 50 may be formed to cover the transparent electrode 20, the interconnection 30, and the printed circuit board 40.

The substrate 10 may include various materials to support the transparent electrode 20 and the interconnection 30. For instance, the substrate 10 may include a glass substrate.

Thereafter, at least one concave part 10a may be formed on the substrate 10. The depth of the concave part 10a may be formed to 50% or less of the thickness of the substrate 10. If the depth of the concave part 10a exceeds 50% of the thickness of the substrate 10, the physical strength of the substrate 10 may be weakened due to the concave part 10a formed in the substrate 10.

The shape of the concave part 10a may be the same as that of the transparent electrode 20 to be formed on the substrate 10. In other words, the shape of the concave part 10a is the very same as the shape of the transparent electrode 20.

Thereafter, the transparent electrode 20 is formed in the concave part 10a of the substrate 10. The transparent electrode 20 may include a printable paste material. For example, the transparent electrode 20 may include a carbon nano-tube (CNT), a conductive polymer, and an Ag nano-tube. The materials may substitute for ITO (indium tin oxide). The materials have an advantage in terms of a price, and may be formed through a simple process.

In addition, since the transparent electrode 20 is formed in the concave part 10a of the substrate 10, the transparent electrode 20 may be prevented from being corroded or damaged due to external conditions.

Thereafter, the interconnection 30 connected to the transparent electrode 20 and the printed circuit board 40 connected to the interconnection 30 are formed. The interconnection 30 may include metal representing superior electrical conductivity. The printed circuit board 40 may include printed circuit boards having various structures. For example, the printed circuit board may include an FPCB (flexible printed circuit board).

The scattering prevention film 50 may cover the transparent electrode 20, the interconnection 30, and the printed circuit board 40. The scattering prevention film 50 prevents fragments from being scattered when the touch panel 100 is broken due to the impact. The scattering prevention film 50 may include various materials and have various structures.

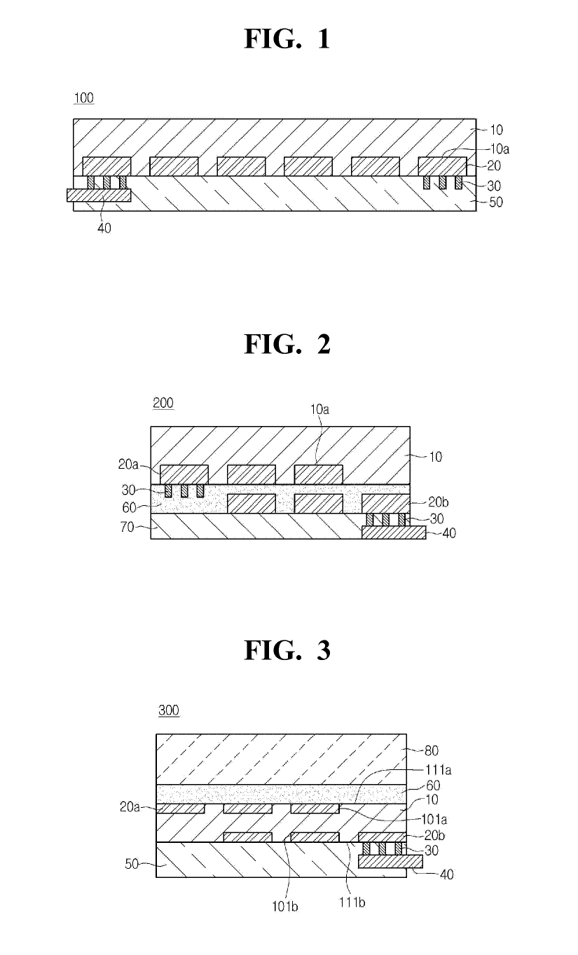

Hereinafter, a touch panel according to the second embodiment will be described in detail with reference to FIG. 2. In the following description, the details of structures and components the same as those of the first embodiment or extremely similar to those of the first embodiment will be omitted except for only structures and components making the difference from those of the first embodiment for the purpose of clear and simple explanation.

FIG. 2 is a sectional view showing a touch panel 200 according to the second embodiment.

Transparent electrodes 20a and 20b of the touch panel 200 according to the second embodiment include a first transparent electrode 20a extending in one direction and a second transparent electrode 20b formed in a direction to cross the first transparent electrode 20a. In this case, the first transparent electrode 20a may be formed in the concave part 10a of the substrate 10, and the second transparent electrode 20b may be formed on a second substrate 70. The second substrate 70 may include a PET (poly (ethylene terephthalate) film or glass.

When the transparent electrode of the 2-layer touch panel is formed, since the first transparent electrode 20a is not formed on an additional panel, but directly formed in the concave part 10a of the substrate 10, the stack structure of the touch panel can be simplified. Accordingly, the transmittance of the touch panel can be improved, and the thickness of the touch panel can be reduced.

In addition, the first and second transparent electrodes 20a and 20b are provided on different layers, so that touch is more sensitively detected. Accordingly, a touch operation can be more exactly performed. In addition, a multi-touch panel, which has been spotlighted recently and can perform a multi-sensing function, can be provided.

Although not shown, in order to prevent the first and second transparent electrodes 20a and 20b from being electrically shorted with each other, an insulating layer (not shown) may be additionally provided between the first and second transparent electrodes 20a and 20b.

An OCA (optically clear adhesive) 60 is provided between the first and second transparent electrodes 20 and 20b, so that the substrate 10 may adhere to the second substrate 70. In addition, the OCA 60 may insulate the first transparent electrode 20a from the second transparent electrode 20b.

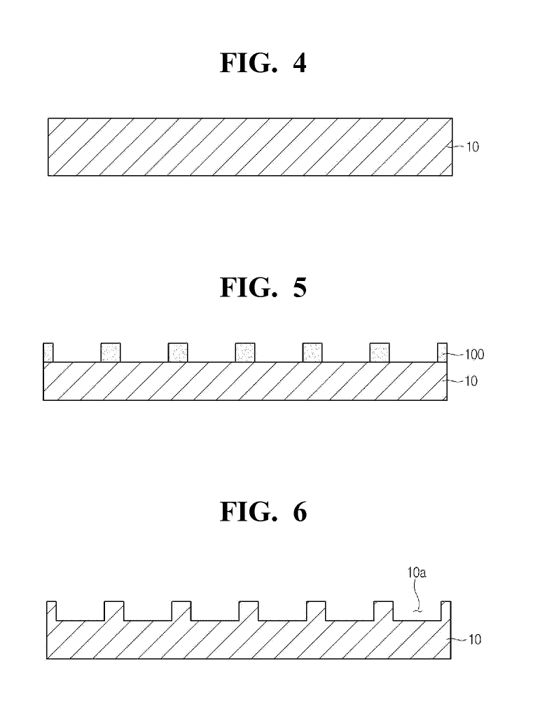

Hereinafter, the touch panel according to the third embodiment will be described in detail with reference to FIG. 3.

FIG. 3 is a sectional view showing the touch panel according to the third embodiment.

In the touch panel 300 according to the third embodiment, the first and second transparent electrodes 20a and 20b are provided on opposite surfaces of the substrate 10. In detail, the substrate 10 includes a top surface 111a making contact with an input device and a bottom surface 111b opposite to the top surface 111a, and includes a first concave part 101a of the top surface 111a and a second concave part 101b of the bottom surface 111b. In this case, the total depth of the first and second concave parts 101a and 101b is formed 50% or less of the thickness of the substrate 10.

Thereafter, the first transparent electrode 20a may be formed in the first concave part 101a, and the second transparent electrode 20b may be formed in the second concave part 101b. The touch panel 300 may include a protective glass layer 80 in order to protect the first transparent electrode 20a formed on the top surface 111a of the substrate 10. The protective glass layer 80 includes a hard coating layer so that the protective glass layer 80 is prevented from being scratched.

Hereinafter, a method for manufacturing the touch panel according to the embodiment will be described in detail with reference to FIGS. 4 to 9. In the following description, the details of structures and components the same as or extremely similar to those described above will be omitted except for only structures and components making the difference from those described above for the purpose of clear and simple explanation.

FIGS. 4 to 9 are sectional views showing the method for manufacturing the touch panel.

As shown in FIG. 4, the substrate 10 applicable to the touch panel is prepared.

Thereafter, as shown in FIGS. 5 and 6, after forming a mask 100 on the substrate 10 except for an electrode part, a portion of the substrate 10 without the mask 100 is etched to form the concave part 10a. The depth of the concave part 10a is formed to 50% or less of the thickness of the substrate 10 through the above etching process.

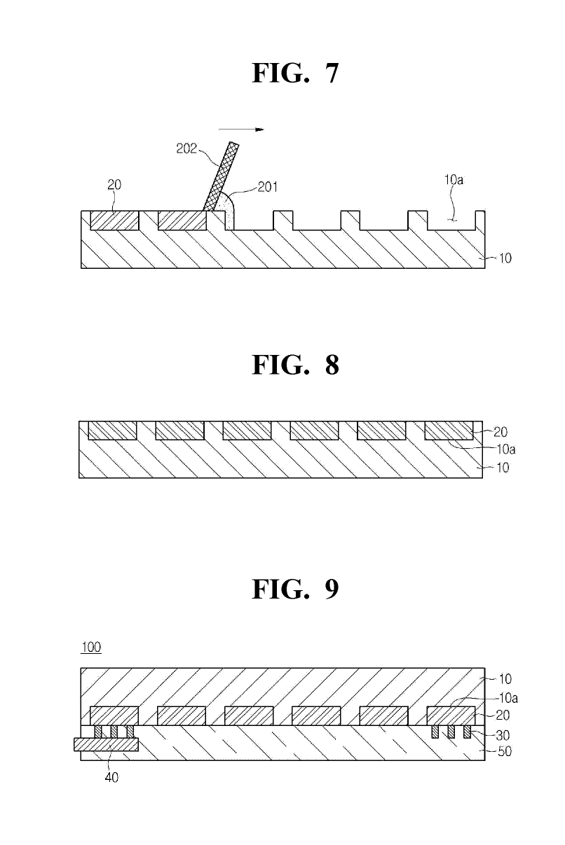

Thereafter, as shown in FIGS. 7 and 8, the electrode 20 is formed through the printing process. In detail, the concave part 10a may be filled with an electrode material 201 by using a doctor blade 202. In other words, the electrode material 201 is filled in the concave part 10a while moving the blade 202 in an arrow direction shown in FIG. 7 in the state that the doctor blade 202 makes contact with the substrate 10. Therefore, the electrode material 201 may include printable paste material instead of conventional ITO. For example, the electrode material 201 may include a carbon nano-tube (CNT), a conductive polymer, and an Ag nano-wire ink.

Conventionally, when the electrode is formed by using the ITO, an evaporation scheme employing a mask is performed to form an electrode pattern. However, according to the present embodiment, since the transparent electrode 20 is formed in the concave part 10a of the substrate 10, the vacuum deposition process may be omitted. In addition, since the transparent electrode 20 is formed through the simple printing process, the manufacturing cost can be reduced.

After the printing process, the process of sintering the transparent electrode 20 formed in the concave part 10a may be formed.

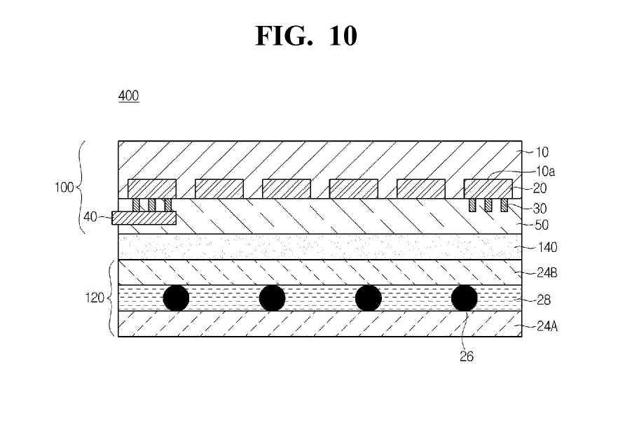

Hereinafter, as shown in FIG. 9, the interconnection 30, the printed circuit board 40, and the scattering prevention film 50 are additionally formed on the substrate 10, so that the touch panel can be manufactured.

Hereinafter, a liquid crystal display including a touch panel will be described with reference to FIG. 10. FIG. 10 is a sectional view schematically showing the liquid crystal display. A liquid crystal display 400 according to the present embodiment may include a liquid crystal panel 120 equipped with the above-described touch panel 100. The touch panel 100 may receive external information from the screen of the liquid crystal panel 120, and may be stacked on the surface of the liquid crystal panel 120. In other words, the touch panel 100 may be bonded to the liquid crystal panel 120 by using an adhesive 140. For example, the adhesive 140 may include an OCA.

The liquid crystal panel 120 serves as a display section of the liquid crystal display device. The liquid crystal panel 120 displays an image by adjusting light transmittance of liquid cells injected into the two pieces of glass substrates. The liquid crystal cells adjust the quantity of light transmitted in response to a video signal, that is, a corresponding pixel signal.

The liquid crystal panel 120 has a liquid crystal material 28 and ball spacers 26 injected between lower and upper glass substrates 24A and 24B. Although not shown in detail, a gate line, an insulating layer, a pixel electrode, and a first alignment layer may be sequentially formed on the lower glass substrate 24A. A black matrix, a color filter, a common electrode, and a second alignment layer may be sequentially formed on the bottom surface of the upper glass substrate 24B. The upper and lower glass substrates 24A and 24B are spaced apart from at a predetermined interval by the ball spacers 26. In other words, the ball spacers 26 maintain the upper and lower glass substrates 24A and 24B at a uniform interval, so that the liquid crystal material 28 may have a uniform thickness.

Although only the liquid crystal display device 400 including the liquid crystal panel 120 bonded to the touch panel 100 according to the first embodiment is shown in FIG. 10, the embodiment is not limited thereto. Accordingly, the present embodiment includes a liquid crystal display device including the liquid crystal panel 120 bonded to the touch panel 200 according to the second embodiment and the touch panel 300 according to the third embodiment.

Any reference in this specification to “one embodiment”,? “an embodiment”, “example embodiment”,? etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Any reference in this specification to “one embodiment,? “an embodiment”,? “example embodiment”,? etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

What is claimed is:

1. A method for manufacturing a touch panel, the method comprising:
preparing a substrate;
forming a concave part in the substrate; and
forming a transparent electrode in the concave part.

2. The method of claim 1, wherein, in the forming of the concave part, a depth of the concave part is formed to 50% or less of a thickness of the substrate.

3. The method of claim 2, wherein, in the forming of the concave part, a photoresist process is included.

4. The method of claim 1, wherein, in the forming of the transparent electrode, a printing process is used.

5. The method of claim 4, wherein, in the forming of the transparent electrode, a transparent electrode material including paste is filled in the concave part.

6. The method of claim 5, wherein, in the forming of the transparent electrode, the transparent electrode material is filled in the concave part by using a doctor unit.
